(19) United States
(12) Patent Application Publication
(10) Pub. No.: US 2015/0311420 A1
(43) Pub. Date: Oct. 29, 2015

(54) THERMOELECTRIC MODULE

(71) Applicant: KYOCERA CORPORATION, Kyoto-shi, Kyoto (JP)

(72) Inventor: Kenichi AKABANE, Kyoto-shi (JP)

(73) Assignee: KYOCERA Corporation, Kyoto-shi, Kyoto (JP)

(21) Appl. No.: 14/647,482

(22) PCT Filed: Nov. 29, 2013
(86) PCT No.: PCT/JP2013/082213

§ 371 Date: May 27, 2015

(30) Foreign Application Priority Data
Nov. 29, 2012 (JP) 2012-260970

(51) Int. Cl. H01L 35/32

(52) U.S. Cl. CPC H01L 35/32

(57) ABSTRACT

A thermoelectric module includes a pair of support substrates; a wiring conductor disposed on each of one main faces opposing each other of the pair of support substrates; and thermoelectric elements electrically connected to the wiring conductor. A sealing member is disposed on a periphery of the region between the one main faces opposing each other of the pair of support substrates. The sealing member has a plurality of voids in an interior thereof.

### TECHNICAL FIELD

The present invention relates to a thermoelectric module for use in a constant temperature bath, a refrigerator, an automotive seat cooler, semiconductor manufacturing equipment, a laser diode, a waste heat-exploiting power generation system, or other purposes.

### BACKGROUND ART

A thermoelectric element is a component utilizing an effect in which, upon the passage of an electric current through a pn junction pair composed of a p-type semiconductor and an n-type semiconductor, one end of each semiconductor generates heat, whereas the other end thereof absorbs heat, called the Peltier effect. A thermoelectric module, which is constructed by designing such a thermoelectric element in modules, is capable of precise temperature control, is small-sized, and has a simple constitution, wherefore it is utilized as temperature control means in a CFC-free cooling apparatus, a light detector, a semiconductor manufacturing apparatus, and so forth, or a device such as a laser diode.

Moreover, in a thermoelectric element, upon causing a temperature difference between the opposite ends thereof, a potential difference is applied between one end and the other end under the Seebeck effect. By exploiting this Seebeck effect, output of power can be produced from the thermoelectric element, and thus, the thermoelectric element is expected to be utilized in power-generating equipment such as a waste heat-exploiting power generator.

A thermoelectric module which is used in the vicinity of room temperature comprises a pair of a p-type thermoelectric element and an n-type thermoelectric element formed of a thermoelectric material made of A₂B₃-type crystal (A represents Bi and/or Sb, and B represents Te and/or Se). For example, as thermoelectric materials having outstanding performance capability, a thermoelectric material made of a solid solution of Bi₂Te₃ and Sb₂Te₃ (antimony telluride) is used for the p-type thermoelectric element, and a thermoelectric material made of a solid solution of Bi₂Te₃ and Bi₂Se₃ (bismuth selenide) is used for the n-type thermoelectric element.

In order to produce a thermoelectric module, the p-type thermoelectric elements and the n-type thermoelectric elements made of such thermoelectric materials are arranged so as to be electrically connected in series with each other on a support substrate made of an insulator such as ceramics having a wiring conductor formed on its surface, and then the p-type thermoelectric element and the n-type thermoelectric element are joined to the wiring conductor by solder. In addition, a heat exchanger member such as a fin is bonded to the support substrate by adhesion using an adhesive, solder, or otherwise for the purpose of effecting heat collection or heat dissipation via a medium such as air or water.

As a way to use the thermoelectric module for thermoelectric generation in waste heat-exploiting power generation applications, a temperature difference is caused between a pair of support substrates of the thermoelectric module by applying heat to one main face of the thermoelectric module from a heat source, and cooling an opposite main face with a gaseous or liquified substance, thereby achieving power generation. Moreover, it is customary to use a heat exchanger member such as a metal fin or metal honeycomb in order to effect heat exchange via a gaseous or liquified substance.

Since waste heat-exploiting power generation systems find applications mainly in incinerators, automobiles, or ships and vessels, it follows that the thermoelectric module may be used in environments where condensation is encountered. It is therefore necessary to take measures against condensation in the thermoelectric module, for example, charging application of a sealing material such as epoxy resin to the outer edge of the module for providing protection for thermoelectric elements. In the event that such an anti-condensation measure is inadequate, there arises the possibility of causing corrosion in thermoelectric elements and in electrodes, or causing damage to the thermoelectric module due to electrode-to-electrode migration.

In Japanese Unexamined Patent Publication JP-A 2008-244100 (hereafter referred to as “Patent Literature 1”), there is a description about the placement of a moisture-proof wall at the outer edge of a thermoelectric module as an anti-condensation measure. In the thermoelectric module described in Patent Literature 1, however, at the time of applying heat to the main face of one side of the thermoelectric module, the heat may inconveniently be transferred to the main face of the other side through the moisture-proof wall. As a result, the degree of difference in temperature between the main face of one side and the main face of the other side is decreased, which leads to a decline in the efficiency of power generation in the thermoelectric module.

### SUMMARY OF INVENTION

According to one aspect of the invention, a thermoelectric module comprises: a pair of support substrates disposed so as to face each other; a wiring conductor disposed on each of one main faces opposing each other of the pair of support substrates; a plurality of thermoelectric elements disposed in arrays in a region between the one main faces opposing each other of the pair of support substrates so as to be electrically connected to the wiring conductor; and a sealing member disposed on a periphery of the region between the one main faces opposing each other of the pair of support substrates, the sealing member having a plurality of voids in an interior thereof.

### BRIEF DESCRIPTION OF DRAWINGS

FIG. 1 is an exploded perspective view showing a thermoelectric module in accordance with one embodiment of the invention;

FIG. 2 is a plan view showing the thermoelectric module in accordance with one embodiment of the invention;

FIG. 3 is a sectional view of the thermoelectric module taken along the line A-A′ shown in FIG. 2;

FIG. 4 is a sectional view showing a thermoelectric module in accordance with another embodiment of the invention;

FIG. 5 is a sectional view showing a thermoelectric module in accordance with another embodiment of the invention;

FIG. 6 is a plan view showing a thermoelectric module in accordance with another embodiment of the invention;

FIG. 7 is a sectional view of the thermoelectric module taken along the line B-B′ shown in FIG. 6; and

FIG. 8 is a graph showing the relationship between the proportion of voids and the amount of power generation.

### DESCRIPTION OF EMBODIMENTS

Hereinafter, a thermoelectric module 10 in accordance with one embodiment of the invention will be described with reference to drawings. Although the present embodiment will be described with respect to a case where the thermoelectric module 10 is used for power generation purposes, a thermoelectric module having a similar constitution can be used for temperature control purposes.

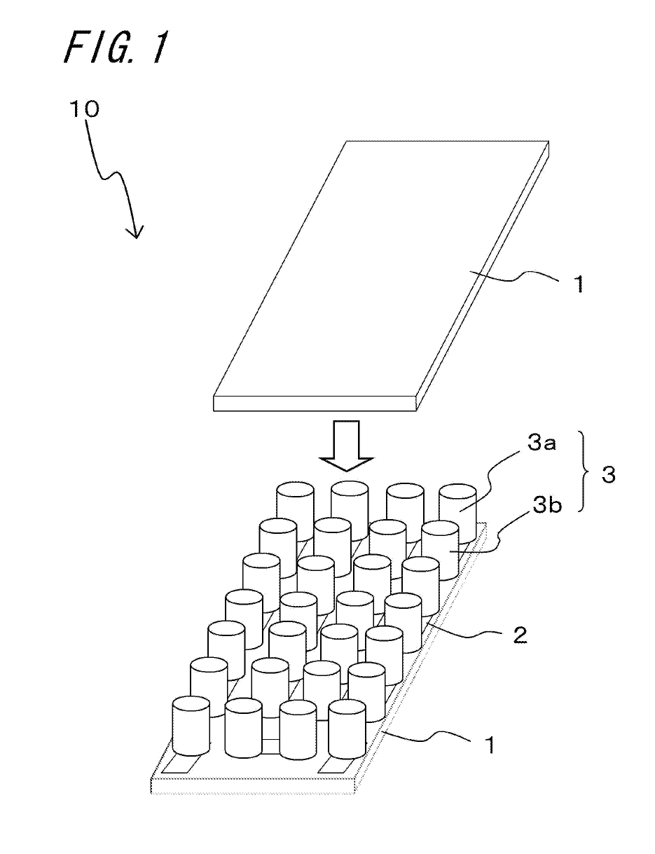

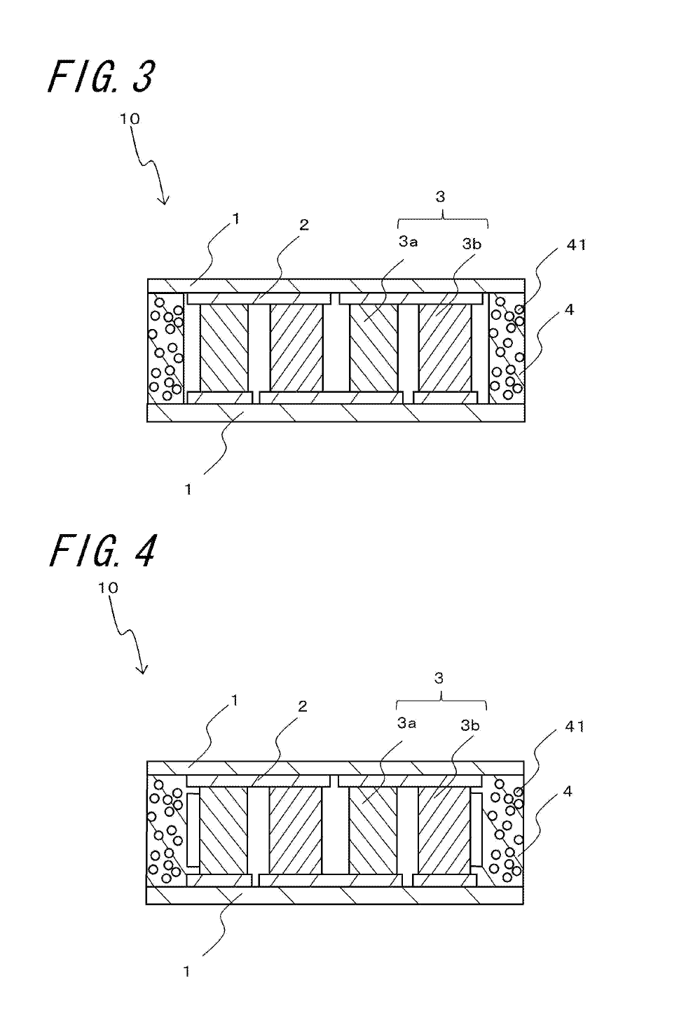

As shown in FIGS. 1 to 3, the thermoelectric module 10 in accordance with one embodiment of the invention comprises: a pair of support substrates 1; a wiring conductor 2 disposed on one main face of the support substrate 1; a thermoelectric element 3 electrically connected to the wiring conductor 2; and a sealing member 4 disposed on the periphery of a region between one main faces of the support substrates 1. In FIG. 1, the diagrammatic representation of the sealing member 4 is omitted.

The support substrates 1 are paired plate members for supporting the thermoelectric element 3. The support substrates 1 are disposed so that their one main faces oppose each other. The wiring conductor 2 is formed on each of the opposed inwardly-facing one main faces of the support substrates 1, wherefore at least a surface of the one main face of the support substrate 1 is made of an insulating material. As an example of the support substrate 1, a substrate obtained by laminating a copper plate on the other main face (the opposite, outward main face) of a plate of alumina filler-added epoxy resin or a ceramic plate such as an alumina plate or an aluminum nitride plate can be used. As another example of the support substrate 1, a substrate obtained by forming an insulating layer made of epoxy resin, polyimide resin, alumina, or aluminum nitride on one main face of a copper plate, a silver plate, or a silver-palladium plate can be used. When viewed in a plan view, the support substrate 1 has a polygonal shape including a quadrangular shape, or a circular or elliptical shape. In a case where the shape of the support substrate 1 is defined by a quadrangle, dimensions of the support substrate can be set at 40 to 70 mm in length, 40 to 70 mm in width, and 0.05 to 3 mm in thickness, for example.

The wiring conductor 2 is a member for electrically connecting the thermoelectric elements 3 presented in an array in series, as well as taking out electric power generated in the thermoelectric elements 3. The wiring conductor 2 is disposed on each of the opposed inwardly-facing one main faces of the pair of support substrates 1. The wiring conductor 2 is disposed in a manner such that the adjacently arranged p-type thermoelectric elements 3a and n-type thermoelectric elements 3b are electrically connected alternately in series with each other. The wiring conductor 2 is made of, for example, copper, silver, or a silver-palladium material. For example, the wiring conductor 2 is formed by bonding a copper plate to one main face of the support substrate 1, and subsequently defining a predetermined pattern in the copper plate by means of etching.

The thermoelectric element 3 is a member for effecting power generation under the Seebeck effect. The thermoelectric elements 3 are classified as the p-type thermoelectric element 3a and the n-type thermoelectric element 3b. The main body of the thermoelectric element 3 (the p-type thermoelectric element and the n-type thermoelectric element) is formed from a thermoelectric material made of A₂B₃-type crystal (A represents Bi and/or Sb, and B represents Te and/or Se), or preferably a Bi (bismuth)- or Te (tellurium)-based thermoelectric material. Specifically, the p-type thermoelectric element 3a is formed from a thermoelectric material made of a solid solution of Bi₂Te₃ (bismuth telluride) and Sb₂Te₃ (antimony telluride). Moreover, the n-type thermoelectric element 3b is formed from a thermoelectric material made of a solid solution of Bi₂Te₃ (bismuth telluride) and Bi₂Se₃ (bismuth selenide).

Here, the thermoelectric material constituting the p-type thermoelectric element 3a is obtained by melting a p-type element constituent material composed of bismuth, antimony, and tellurium once, and subsequently solidifying a molten material unidirectionally into a rod-like form by the Bridgman method. Moreover, the thermoelectric material constituting the n-type thermoelectric element 3b is obtained by melting an n-type element constituent material composed of bismuth, tellurium, and selenium once, and subsequently solidifying a molten material unidirectionally into a rod-like form by the Bridgman method.

After a coating of a resist is applied to side faces of these thermoelectric materials to prevent adhesion of plating, the materials are each cut in a thickness of, for example, 0.3 to 5 mm with use of a wire saw. Next, a nickel layer and a tin layer are sequentially formed on the cut surfaces alone by means of electrolytic plating. Lastly, the resist is removed by a dissolving solution. In this way, the thermoelectric element 3 (the p-type thermoelectric element 3a and the n-type thermoelectric element 3b) can be obtained.

The thermoelectric element 3 (the p-type thermoelectric element 3a and the n-type thermoelectric element 3b) can be made to have a circular cylindrical shape, a quadrangular shape, or other polygonal shape, for example. It is particularly desirable to form the thermoelectric element in a circular cylindrical shape. This helps lessen the influence of thermal stress developed in the thermoelectric element 3 under heat cycles. In the case of imparting a circular cylindrical shape to the thermoelectric element 3, as to its dimensions, the length is the same as that described above, and, the diameter falls in the range of 1 to 3 mm, for example.

In the thermoelectric elements 3, as shown in FIG. 1, a plurality of p-type thermoelectric elements 3a and a plurality of n-type thermoelectric elements 3b are alternately arranged in a matrix form at a spacing which is 0.5 to 2 times the diameter of the thermoelectric element 3. The thermoelectric elements 3 are joined to their respective wiring conductors 2 by a solder paste applied in a pattern similar to the pattern of the wiring conductor 2. Thus, a plurality of the thermoelectric elements 3 can be electrically connected alternately in series with each other by the wiring conductors 2.

The sealing member 4 is a member for surrounding and sealing a plurality of the thermoelectric elements 3. With the placement of the sealing member 4, the thermoelectric elements 2 can be protected from the influence of a surrounding environment, with consequent improvement in the resistance to environment of the thermoelectric module 10. The sealing member 4 is disposed in frame form on the periphery of the region between the one main faces opposing each other of the pair of support substrates 1 so as to surround arrays of a plurality of the thermoelectric elements 3. Thus, the sealing member 4, in conjunction with the pair of support substrates 1, hermetically seals the thermoelectric elements 3. The sealing member 4 is made of a resin material such for example as urethane resin, polypropylene resin, polyethylene resin, or epoxy resin. The width of the sealing member 4 is adjusted to fall in the range of 0.2 to 5 mm in a direction along one main face of the support substrate 1. Moreover, the thickness of the sealing member 4 is equal to the distance between the pair of support substrates 1 defined by the length of the thermoelectric element 3. As a way to form the sealing member 4, for example, a dispenser application method can be employed.

The sealing member 4 has a plurality of voids 41 therein. By providing a plurality of voids 41 within the sealing member 4, the thermal conductivity of the sealing member 4 is lowered, wherefore heat transfer from one of the support substrates 1 to the other support substrate 1 through the sealing member 4 can be reduced. This helps suppress the lessening of the difference in temperature between one main face of one of the support substrates 1 and one main face of the other opposite support substrate 1. As a result, the efficiency of power generation in the thermoelectric module 10 can be increased. As to the dimensions of the void 41, given that the sealing member 4 has a thickness of about 3 mm, then it is advisable to adjust the diameter of the void 41 to fall in the range of 0.1 to 1 mm, for example.

The voids 41 are preferably provided so that, when the sealing member 4 is viewed in a section perpendicular to the main face of the support substrate 1, the proportion of the sum of the areas of the voids 41 to the total area of the sealing member 4 (including parts constituting the voids 41) is equal to about 30 to 50%. In a case where the voids 41 occupy an area greater than or equal to 30% of the area of the sealing member 4, the thermal conductivity of the sealing member 4 can be lowered effectively, which is effective in suppression of heat transfer through the sealing member 4. Moreover, in a case where the voids 41 occupy an area less than or equal to 50% of the area of the sealing member 4, it never occurs that the strength of the sealing member 4 decreases excessively, and that the voids 41 combine to create an air passageway penetrating through the sealing member 4, wherefore the sealing member is capable of effective hermetic sealing.

The ratio of the sectional areas of the voids 41 to the sectional area of the sealing member 4 can be determined in the following manner. To begin with, the thermoelectric module 10 is cut for observing the section of the sealing member 4 by means of a scanning electron microscope (SEM). Then, on the basis of the section, the sum of the areas of the voids 41 is divided by the area of the sealing member 4, whereby the proportion of the voids 41 can be determined.

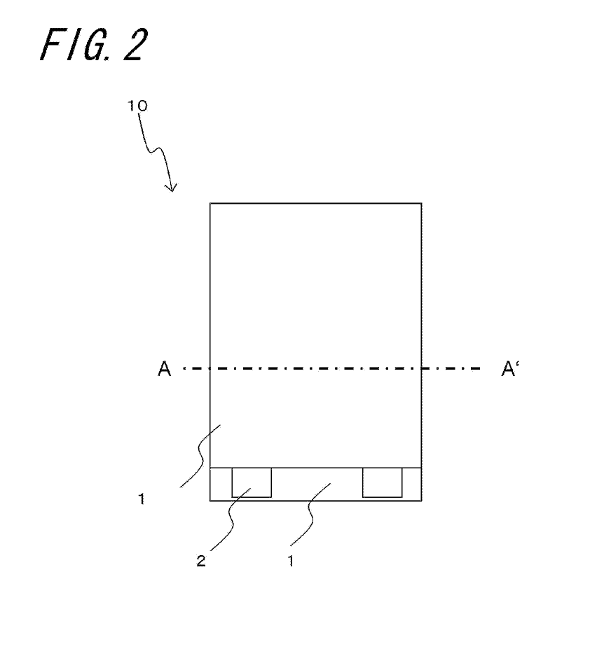

As shown in FIG. 2, in a case where the support substrate 1 has a polygonal shape (quadrangular shape, in this embodiment), a plurality of voids 41 are preferably provided in a part of the sealing member 4 corresponding to a corner part of the support substrate 1. In the thermoelectric module 10, power generation is effected by causing a temperature difference between the opposite main faces of the thermoelectric module 10. Since the support substrate 1 to be heated will undergo expansion due to thermal expansion, it follows that the thermoelectric module 10 may be warped. At this time, the warpage of the corner part toward the outer surface of one of the support substrates 1 may cause the corner part of one of the support substrates 1 to make contact with a heat source. In this regard, in the presence of a plurality of voids 41 in the part of the sealing member 4 corresponding to the corner part which receives the largest quantity of inflow heat, heat transfer to the other one of the support substrates 1 can be reduced effectively. As a result, the efficiency of power generation in the thermoelectric module 10 can be increased.

Moreover, in the case where the support substrate 1 has a polygonal shape, it is preferable that the voids 41 exist throughout the sealing member 4, and that a larger number of the voids 41 exist in the part of the sealing member 4 corresponding to the corner part of the support substrate 1 than in a remaining part of the sealing member 4. The expression “larger number of the voids 41” as suggested herein means that, when the sealing member 4 is viewed in a section perpendicular to the main face of the support substrate 1, the proportion of an area occupied by the voids 41 in the corner part is greater than the proportion of an area occupied by the voids 41 in a remaining part other than the corner part. Specifically, given that the proportion of the area occupied by the voids 41 in the part other than the corner part is 30%, then the proportion of the area occupied by the voids 41 in the corner part is advisably 40%, for example.

In this case, heat transfer to the other support substrate 1 can be reduced even further. Moreover, in the case of adjusting the smaller number of the voids 41 in the remaining part than in the corner part, as contrasted to a case where a large number of voids 41 are formed throughout the sealing member 4, the strength of the sealing member 4 can be increased. This makes it possible to suppress damage to the part of the sealing member 4 corresponding to the corner part of the support substrate 1, and thereby improve the durability of the thermoelectric module 10.

Moreover, it is preferable that the voids 41 exist throughout the sealing member 4, and that a larger number of the voids 41 exist in a part of the sealing member 4 which is particularly closer to the support substrate 1 than in a remaining part of the sealing member 4. The expression “larger number of the voids 41” as suggested herein means that, as has already been described, when the sealing member 4 is viewed in a section, the proportion of the area occupied by the voids 41 in the former part is greater than that in the latter part. By so doing, the heat transferred to the sealing member 4 can be reduced effectively. Moreover, in this case, as contrasted to a case where a large number of voids 41 are formed throughout the sealing member 4, the strength of the sealing member 4 can be maintained effectively. This makes it possible to improve the durability of the thermoelectric module 10.

Moreover, it is preferable that the voids 41 exist throughout the sealing member 4, and that a larger number of the voids 41 exist in a part of the sealing member 4 which is located toward the inner periphery of the thermoelectric module 10 than in a part of the sealing member 4 which is located toward the outer periphery of the thermoelectric module 10. The expression “larger number of the voids 41” as suggested herein means that, as has already been described, when the sealing member 4 is viewed in a section, the proportion of the area occupied by the voids 41 in the former part is greater than that in the latter part. Thus, by providing a larger number of the voids 41 in that part of the sealing member 4 which is closer to the thermoelectric element 3, the difference in temperature between the upper portion and the lower portion of the thermoelectric element 3 can be ensured with ease. Moreover, by providing a smaller number of voids 41 in that part of the sealing member 4 which is located toward the outer periphery of the thermoelectric module 10, the degree of internal hermeticity of the thermoelectric module 10 can be increased. As a result, it is possible to achieve improvement in power generation efficiency while maintaining the reliability of the thermoelectric module 10.

It is particularly preferable that the voids 41 exist throughout the sealing member 4, that the proportion of an area occupied by the voids 41 in that part of the sealing member 4 which is located toward the inner periphery of the thermoelectric module 10 is greater than the area proportion in that part of the sealing member 4 which is located toward the outer periphery thereof, and that the size of each void 41 in the inner periphery-sided part of the sealing member 4 is smaller than the void size in the outer periphery-sided part thereof. By dispersing finer voids 41 in the inner periphery-sided part, the heat resistance of the sealing member 4 can be raised. This makes it possible to ensure the difference in temperature between the upper portion and the lower portion of the thermoelectric element 3 with greater ease. As a result, the efficiency of power generation in the thermoelectric module 10 can be increased even further.

Moreover, it is preferable that the hermetically-sealed space surrounded with the sealing member 4 and the pair of support substrates 1 is kept in a pressure-reduced condition. Under the pressure-reduced condition, heat transfer between the support substrates 1 via a gaseous substance can be reduced. This helps increase the efficiency of power generation in the thermoelectric module 10. Exemplary of the pressure-reduced condition is a condition at about 0.3 to 0.7 atm.

Moreover, as shown in FIG. 4, the sealing member 4 is preferably disposed so as to at least partly cover a junction between the wiring conductor 2 and the thermoelectric element 3 placed in the proximity of the periphery. In this case, even if a thermal stress is developed between the thermoelectric element 3 and the wiring conductor 2, occurrence of separation of the thermoelectric element 3 from the wiring conductor 2 can be suppressed. Moreover, it is preferable that the sealing member 4 covers at least part of the aforementioned junction but does not make contact with other parts of the thermoelectric element 3. This makes it possible to suppress occurrence of separation of the thermoelectric element 3 as described above while reducing unnecessary heat transfer from the thermoelectric element 3 to the sealing member 4.

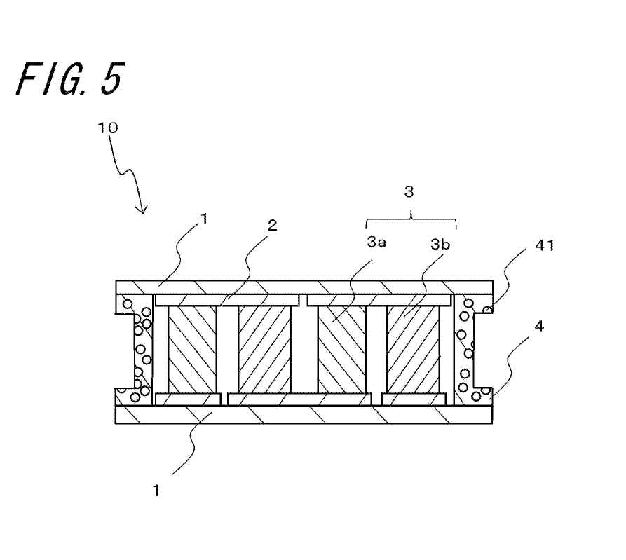

Moreover, as shown in FIG. 5, it is preferable that the sealing member 4 has a portion having a narrower width in a direction along one main face of the support substrate 1. By forming such a portion, heat transfer from one of the support substrates 1 to the other through the sealing member 4 can be reduced even further.

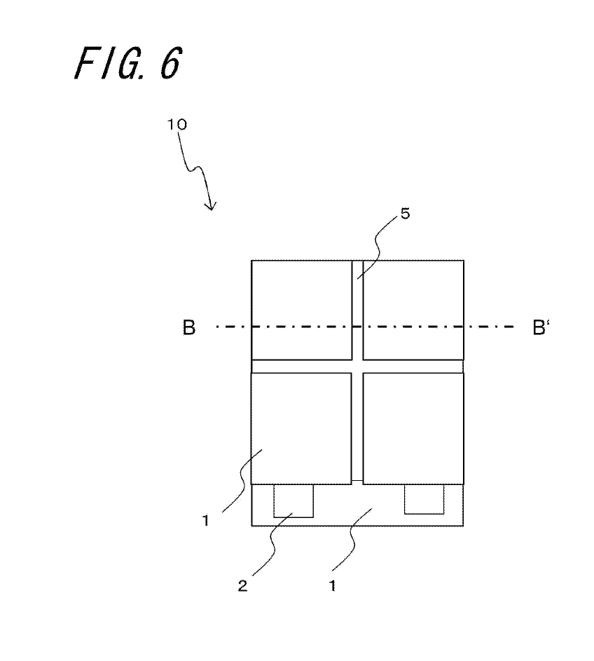

Moreover, as shown in FIG. 6, at least one of the paired support substrates 1 may be divided to create slit-like clearances. This helps suppress occurrence of warpage in the support substrate 1. Note that the slit-like clearance may be obtained either by forming a linear gap partly in the support substrate 1 or by forming a gap so as to effect partitioning of the support substrate 1. In other words, the support substrate 1 may be split into two or more members.

Moreover, a second sealing member 5 may be placed in the slit-like clearance. A material similar to the material used for the sealing member 4 can be used for the second sealing member 5. With the placement of the second sealing member 5, even if the slit-like clearance is formed, the thermoelectric element 3 can be hermetically sealed. Furthermore, it is preferable that the second sealing member 5 has a plurality of voids 51. By providing the voids 51 in the second sealing member 5, when a thermal stress is developed between the support substrate 1 and the second sealing member 5, the second sealing member 5 is allowed to flex adequately while ensuring hermeticity. This helps decrease the possibility of causing thermal stress-induced damage to the second sealing member 5 with consequent deterioration in hermeticity.

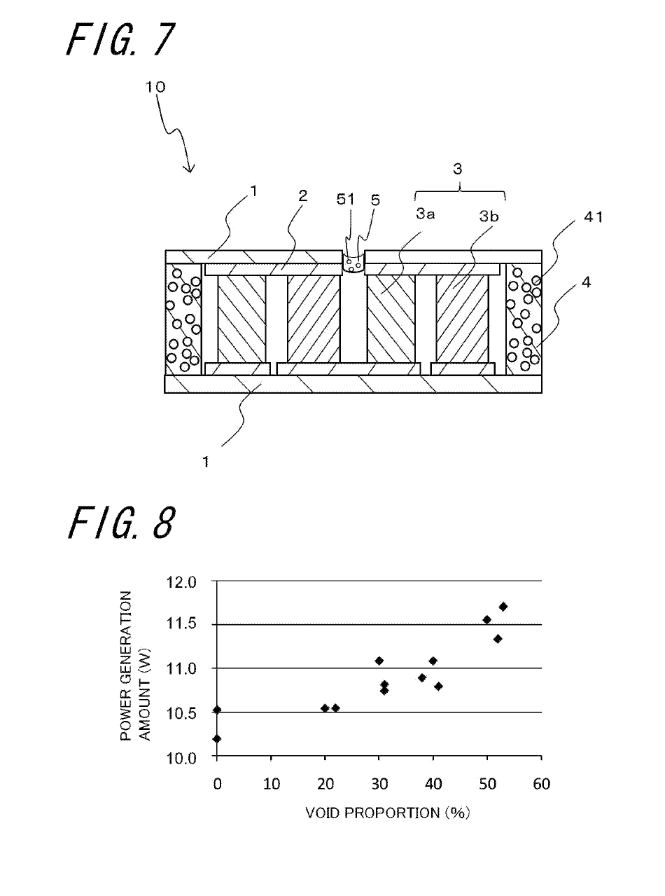

Moreover, as shown in FIG. 7, it is preferable that the second sealing member 5 is curved toward the region between the one main faces opposing each other of the pair of support substrates 1. This helps decrease the possibility of bringing the second sealing member 5 into contact with a heat source. Accordingly, heat transfer to the second sealing member 5 can be reduced. As a result, the influence of thermal stress in the second sealing member 5 can be decreased even further.

As to the dimensions of the second sealing member 5, for example, its width can be adjusted to fall in the range of 0.05 to 3 mm, and its depth can be adjusted to fall in the range of 0.01 to 3 mm. Moreover, the second sealing member 5 is curved so that the radius of curvature of its outer peripheral surface falls in the range of 0.25 to 2.5 mm, for example.

The thermoelectric module 10 thus far described can be produced in the following manner.

To begin with, the thermoelectric element 3 (the p-type thermoelectric element 3a and the n-type thermoelectric element 3b) is joined with the support substrate 1. Specifically, a solder paste or a joining material made of a solder paste is applied to at least part of the wiring conductor 2 formed on the support substrate 1, thereby forming a solder layer. As an application method, a screen printing technique using a metal mask or screen mesh is desirable from the cost and mass-production standpoint.

Next, the thermoelectric elements 3 are arranged on the surface of the wiring conductor 2 coated with the joining material (solder). Two types of elements composed of the p-type thermoelectric elements 3a and the n-type thermoelectric elements 3b are arranged alternately.

After that, the support substrate 1 with the wiring conductor 2 whose surface has been coated with solder is soldered to the upper surfaces of the thermoelectric elements 3 (the p-type thermoelectric elements 3a and the n-type thermoelectric elements 3b) by a heretofore known technique. Although the soldering can be conducted by either of a reflow-furnace heating method and a heater heating method, in a case where resin is used for the support substrate 1, it is desirable to perform heating while applying pressure to the upper and lower surfaces of the structure from the viewpoint of enhancing the adhesion between the solder and the thermoelectric elements 3 (the p-type thermoelectric elements 3a and the n-type thermoelectric elements 3b).

Next, in order to seal the outer periphery of the thermoelectric module 10, a material for constituting the sealing member 4 is applied to the outer periphery at the region between the support substrates 1 by means of printing, a dispenser, or otherwise. For example, epoxy resin is used as the material for constituting the sealing member 4. Then, the structure is subjected to vacuum evacuation so that it is put in an environment at 0.3 to 0.7 atm, thereby foaming the material for constituting the sealing member 4. The thereby foamed material for constituting the sealing member 4 has voids 41 in an interior thereof. Upon curing this material, the sealing member 4 having the voids 41 is formed. Note that a gaseous substance existing within a space sealed by the sealing member 4 may expand when performing vacuum evacuation, which gives rise to the possibility that the position of the outer periphery of the sealing member 4 is displaced outwardly from the position of the outer periphery of the support substrate 1. In this regard, by locating the outer periphery of the sealing member 4 inwardly of the outer periphery of the support substrate 1 in advance, the sealing member 4 can be set in a proper position upon completion of vacuum evacuation.

Moreover, an increase in the amount of voids 41 to be formed can be achieved by the following methods. Specifically, the amount of the voids 41 can be increased by prolongation of the evacuation time, lowering of pressure, or reduction of the viscosity of the material for constituting the sealing member 4.

Moreover, the distribution of the voids 41 can be adjusted by the following methods. Specifically, in a part where it is desired to create a larger number of the voids 41, a method for decreasing the viscosity of the material for constituting the sealing member 4 can be employed. By so doing, it is possible to increase the amount of voids 41 to be created during foaming process partly in the sealing member. For example, admixture of a diluent can be adopted as the method for decreasing the viscosity of the material for constituting the sealing member 4. In a case where the sealing member 4 is made of epoxy resin, in the part where it is desired to create a larger number of the voids 41, the amount of a diluent to be added is increased so that the viscosity stands at about 1 to 10 Pa·s at room temperature, for example. On the other hand, in a part where it is desired to create a smaller number of voids 41, the amount of a diluent to be added is reduced so that the viscosity stands at about 70 to 130 Pa·s at room temperature, for example. This method may be employed for, for example, the case of creating a larger number of the voids 41 in the corner part of the sealing member 4.

Moreover, in a case where a material difficult to be foamed by vacuum evacuation is used as the material for constituting the sealing member 4, it is possible to employ a method of applying the material for constituting the sealing member 4 onto a foamed body placed in advance at a location where the sealing member 4 is applied. For example, beads made of polyethylene, polypropylene, or the like may be used as the foamed body.

Lastly, a lead wire for taking out produced electric current is joined to a pad drawn from the wiring conductor 2 of the support substrate 1 onto, for example, the other main face by means of soldering iron, laser, or the like, whereupon the thermoelectric module 10 can be obtained.

### EXAMPLES

Hereinafter, the invention will be particularized by way of practical examples.

To begin with, n-type and p-type thermoelectric materials made of bismuth, antimony, tellurium, and selenium were melted and solidified in accordance with the Bridgman method to produce 1.8 mm-diameter rod-like materials each having a circular sectional profile. Specifically, the n-type thermoelectric material is prepared from a solid solution of Bi₂Te₃ (bismuth telluride) and Bi₂Se₃ (bismuth selenide), and the p-type thermoelectric material is prepared from a solid solution of Bi₂Te₃ (bismuth telluride) and Sb₂Te₃ (antimony telluride). For the purpose of surface roughening, the surfaces of the rod-like n-type and p-type thermoelectric materials were etched with nitric acid.

Next, each of the rod-like n-type thermoelectric material and the rod-like p-type thermoelectric material covered with a cover layer was cut so that its height (thickness) becomes 1.6 mm by means of a wire saw to obtain an n-type thermoelectric element 3b and a p-type thermoelectric element 3a. A nickel layer was formed on the cut surfaces of the thereby obtained p-type thermoelectric element 3a and n-type thermoelectric element 3b by means of electrolytic plating.

Next, there was prepared a copper-made support substrate 1 in which a 80 μm-thick epoxy resin-made insulating layer was formed on one main face and a 105 μm-thick wiring conductor 2 was formed on the insulating layer (60 mm in length, 60 mm in width, and 200 μm in thickness). Then, a solder paste was applied onto the wiring conductor 2 by means of screen printing.

Moreover, on the solder paste were arranged 310 p-type thermoelectric elements 3a and 310 n-type thermoelectric elements 3b so that the p-type thermoelectric elements 3a and the n-type thermoelectric elements 3b are electrically connected alternately in series with each other by means of a mounter. The thereby arranged p-type thermoelectric elements 3a and n-type thermoelectric elements 3b were set so as to be held between two support substrates 1, and the structure has been heated in a reflow furnace, with its upper and lower surfaces subjected to pressure, whereby the wiring conductor 2 was joined to the thermoelectric elements 3 via solder. Next, a flame retardant tape was wound about the outer periphery of the structure, and, as the sealing member 4, epoxy resin was applied thereon in a thickness of 1.5 mm by a dispenser. After that, as for sample Nos. 1 and 2, the epoxy resin in an as-is state was thermally cured at a temperature of 80° C. for 1 hour so that the voids 41 were not created. Moreover, as for sample Nos. 3 to 18, the epoxy resin was foamed in a pressure-reduced condition, and whereafter thermally cured at a temperature of 80° C. for 1 hour so that the voids 41 were created.

Next, each of the thereby assembled thermoelectric modules was evaluated. The amount of power generation in each of the sample Nos. 1 to 18 was measured in a condition where a temperature difference of about 200° C. was present between the upper side and the lower side of the thermoelectric module in air. In addition, leakage check was conducted to examine the hermeticity of the sealing member 4. Further, the proportion of an area occupied by the voids 41 in the section of the sealing member 4 was measured. The result of evaluation is listed in Table 1.

TABLE 1

| | Void | Power | |
|---|---|---|---|
| | proportion | generation | |
| Sample No. | (%) | amount (W) | Hermeticity |
| 1 | 0 | 10.20 | Good |
| 2 | 0 | 10.53 | Good |
| 3 | 20 | 10.55 | Good |
| 4 | 22 | 10.55 | Good |
| 5 | 30 | 11.09 | Good |
| 6 | 31 | 10.82 | Good |
| 7 | 31 | 10.75 | Good |
| 8 | 38 | 10.90 | Good |
| 9 | 40 | 11.09 | Good |
| 10 | 41 | 10.80 | Good |
| 11 | 50 | 11.56 | Good |
| 12 | 52 | 11.34 | Good |
| 13 | 53 | 11.71 | Good |
| 14 | 61 | Not measured | Poor |
| 15 | 62 | Not measured | Poor |
| 16 | 70 | Not measured | Poor |
| 17 | 75 | Not measured | Poor |
| 18 | 78 | Not measured | Poor |

From the evaluation result, it has been confirmed that no void 41 was formed in each of the sample Nos. 1 and 2. It has also been confirmed that the voids 41 were formed in the sample Nos. 3 to 18. Moreover, the result of the leakage check showed that, in the sample Nos. 14 to 18 in which the proportion of the area occupied by the voids 41 exceeds 60%, hermeticity was not ensured. Therefore, the sample Nos. 14 to 18 were not evaluated in respect of the amount of power generation. The sample Nos. 3 to 13 in which the sealing member 4 bore the voids 41 were found to be greater in power generation amount than the sample Nos. 1 and 2 in which the sealing member 4 was free of the voids 41. The cause for hermeticity deterioration in the sample Nos. 14 to 18 is that, probably, too large a proportion of the area occupied by the voids 41 led up to formation of a hole in the sealing member 4, thus causing communication between the interior of the thermoelectric module 10 and the exterior thereof.

In FIG. 8, there is shown the relationship between the proportion of an area occupied by the voids 41 and the amount of power generation in the sample Nos. 1 to 13.

It has been found from the figure that, in the case where the proportion of an area occupied by the voids 41 is greater than or equal to 30%, the amount of power generation is greatly increased. This is because, probably, by adjusting the proportion of an area occupied by the voids 41 in the sealing member 4 to be greater than or equal to 30%, the extent of heat transfer through the sealing member 4 can be minimized. Moreover, as described above, in the case where the proportion of an area occupied by the voids 41 exceeds 60%, there is a possibility that hermeticity cannot be ensured, but, in fact, hermeticity could be ensured in the case where the area proportion is 53%. It will thus be seen that a desirable proportion of an area occupied by the voids 41 is greater than or equal to 30%, but less than or equal to 53%.

### REFERENCE SIGNS LIST

1: Support substrate
2: Wiring conductor
3: Thermoelectric element
3a: P-type thermoelectric element
3b: N-type thermoelectric element
4: Sealing member
41, 51: Void
5: Second sealing member
10: Thermoelectric module

1. A thermoelectric module, comprising:
a pair of support substrates disposed so as to face each other;
a wiring conductor disposed on each of one main faces opposing each other of the pair of support substrates;
a plurality of thermoelectric elements disposed in arrays in a region between the one main faces opposing each other of the pair of support substrates so as to be electrically connected to the wiring conductor; and
a sealing member disposed on a periphery of the region between the one main faces opposing each other of the pair of support substrates,
the sealing member having a plurality of voids in an interior thereof.

2. The thermoelectric module according to claim 1,
wherein, when the sealing member is viewed in a section perpendicular to the one main faces of the support substrates, the voids are present in the sealing member so as to account for greater than or equal to 30% and less than or equal to 53% of an area of the sealing member.

3. The thermoelectric module according to claim 1,
wherein, when viewed in a plan view, the pair of support substrates has a polygonal shape, and
the plurality of voids are provided in a part of the sealing member corresponding to a corner part of the support substrate.

4. The thermoelectric module according to claim 1,
wherein, when viewed in a plan view, the pair of support substrates has a polygonal shape, and
the voids exist throughout the sealing member, and a larger number of the voids exist in a part of the sealing member corresponding to a corner part of the support substrate than in a remaining part of the sealing member.

5. The thermoelectric module according to claim 1,
wherein a space which is formed between the one main faces opposing each other and is surrounded with the sealing member is kept in a pressure-reduced condition.

6. The thermoelectric module according to claim 1,
wherein the sealing member is disposed so as to at least partly cover a junction between the wiring conductor and the thermoelectric element placed in proximity to the periphery.

7. The thermoelectric module according to claim 1,
wherein the sealing member has a portion having a smaller thickness in a direction along the one main face of the support substrate.

8. The thermoelectric module according to claim 1,
wherein at least one of the pair of support substrates is divided to form a slit-like clearance, and
a second sealing member bearing a plurality of voids is disposed in the slit-like clearance.

9. The thermoelectric module according to claim 8,
wherein the second sealing member is curved toward the region between the opposed one main faces.
